(19) United States
(12) Patent Application Publication
(10) Pub. No.: US 2023/0320171 A1
(43) Pub. Date: Oct. 5, 2023

(54) DISPLAY DEVICE

(71) Applicant: Samsung Display Co., Ltd., Yongin-Si (KR)

(72) Inventors: Young Ok PARK, Seoul (KR); Jun Woo YOU, Seongnam-si (KR); Jung Hyun SHIN, Suwon-si (KR)

(21) Appl. No.: 18/092,344

(22) Filed: Jan. 2, 2023

(30) Foreign Application Priority Data
Mar. 31, 2022 (KR) 10-2022-0040442

(51) Int. Cl. H10K 59/80; H10K 39/34

(52) U.S. Cl. CPC H10K 59/80; H10K 39/34; H10K 59/12

(57) ABSTRACT

Provided is a display device including a substrate, a light-emitting element disposed on the substrate and configured to emit light, a photoelectric conversion element configured to detect incident light, and a window disposed on the light-emitting element and the photoelectric conversion element and configured to transmit light. The window includes a plurality of through holes that overlap the photoelectric conversion element in a thickness direction of the substrate, and a filling member disposed in the plurality of through holes.

### CROSS-REFERENCE TO RELATED APPLICATION

This application claims priority to Korean Patent Application No. 10-2022-0040442 filed on Mar. 31, 2022, and all the benefits accruing therefrom under 35 U.S.C. § 119, the content of which in its entirety is herein incorporated by reference.

### BACKGROUND

### 1. Technical Field

The present disclosure generally relates to a display device. More particularly, the present disclosure relates to a display device capable of recognizing a clear fingerprint image by minimizing the amount of noise light incident on a photo sensor.

### 2. Description of the Related Art

Display devices are widely used for electronic devices, for example, smartphones, tablet computers, notebook computers, monitors, televisions, etc. Recently, with the advancement of a mobile communication technology, the use of portable electronic devices, such as smartphones, tablets, and notebook computers, has been greatly increased. Personal privacy information may be stored in the portable electronic devices. Therefore, to protect the personal privacy information in the portable electronic devices, fingerprint verification for verifying a fingerprint, which is user's biometric information, may be used.

For example, display devices may verify a user's fingerprint using an optical method, an ultrasonic method, or a capacitive method. The optical method may verify the user's fingerprint by detecting light reflected from the user's fingerprint. A display device may include a display panel including pixels configured to display an image and photo sensors configured to detect light in order to verify a user's fingerprint using the optical method.

### SUMMARY

Aspects of the present disclosure provide a display device which can recognize a clear fingerprint image by minimizing the amount of noise light incident on a photo sensor.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a substrate, a light-emitting element disposed on the substrate, a photoelectric conversion element configured to detect light from the plurality of light-emitting portions, and a window disposed on the light-emitting element and the photoelectric conversion element and configured to transmit light. A plurality of through holes that overlap the photoelectric conversion element in a thickness direction of the substrate are defined in the window, and each of a plurality of filling members is disposed in each of the plurality of through holes.

Each of the filling members may be configured to transmit light in a visible light wavelength range.

Each of the filling members may be configured to block light in a wavelength range other than the visible light wavelength range.

A thickness of the window may be 0.2 millimeter (mm) or more.

A thickness of the window may be less than 0.2 mm.

Each of the filling members may include one of silicon resin, urethane resin, acryl resin, epoxy resin, phenolic resin, polyamide resin, and polyimide resin.

Each of the filling members may have a functional group of a thiol-ene group.

A refractive index of the filling member may be 95% to 105% of a refractive index of the window.

The light emitted from the light-emitting element may have a wavelength range of visible light, and a diameter in one direction of each of the plurality of through holes may be the same as the wavelength range of the visible light.

The diameter in one direction of each of the plurality of through holes may be 410 nanometer (nm) to 580 nm.

Each of the plurality of through holes may extend in parallel to the thickness direction of the substrate.

A height of each of the plurality of through holes in the thickness direction of the substrate may be the same as a height of the window.

Each of the plurality of through holes may have a circular shape in a plan view.

Each of the plurality of through holes may have a linear shape extending in one direction in a plan view.

The light-emitting element may include a pixel electrode, a light-emitting layer, and a common electrode which are sequentially stacked in the thickness direction of the substrate, and the photoelectric conversion element may include a first electrode, a photoelectric conversion layer, and the common electrode which are sequentially stacked in the thickness direction of the substrate.

According to an embodiment of the present disclosure, a display device includes a substrate, a plurality of light-emitting portions disposed on the substrate, a plurality of light-sensing portions disposed on the substrate and configured to detect light from the plurality of light-emitting portions, a bank configured to partition the plurality of light-emitting portions and the plurality of light-sensing portions, and a window disposed on the bank. The window includes a plurality of light-guiding areas that overlap the plurality of light-sensing portions in a thickness direction of the substrate. Each of a plurality of through holes is defined in each of the plurality of light-guiding areas, and a plurality of filling members are disposed in the plurality of through holes. The window and the filling member are transparent.

A refractive index of the filling member may be 95% to 105% of a refractive index of the window.

Each of the plurality of light guiding areas may be disposed between a plurality of light-emitting portions adjacent to each other in a first direction and may be disposed between a plurality of light-emitting portions adjacent to each other in a second direction that intersects the first direction.

A number of through holes disposed in one of the plurality of light-guiding areas may be at least 12 or more.

The plurality of through holes may not overlap the bank in the thickness direction of the substrate.

The display device may further include a light blocking layer disposed between the bank and the window and configured to block light. A light-transmitting hole that transmits light is defined in the light blocking layer, and a diameter in one direction of the light-transmitting hole may be narrower than a diameter in one direction of the light-sensing portion.

The light-emitting portion may be defined by a pixel electrode disposed on the substrate, the bank configured to expose the pixel electrode, and a common electrode disposed on the pixel electrode, and the light-sensing portion may be defined by a first electrode disposed on the substrate, the bank configured to expose the first electrode, and the common electrode disposed on the first electrode.

According to an embodiment of the disclosure, the plurality of through holes and the filling member are included, thereby minimizing or reducing the amount of noise light incident on the photo sensor. Also, with the filling member disposed in the through holes, the through holes may not be visually recognized from the outside of the window. Accordingly, the photo sensor of the display device may recognize a clear fingerprint image.

It should be noted that effects of the present disclosure are not limited to those described above and other effects of the present disclosure will be apparent to those skilled in the art from the following descriptions.

### BRIEF DESCRIPTION OF THE DRAWINGS

The above and other features of the present disclosure will become more apparent by describing in detail embodiments thereof with reference to the accompanying drawings, in which:

FIG. 1 is a perspective view of a display device according to an embodiment;

FIG. 2 is a perspective view illustrating a display panel and window of a display device according to an embodiment;

FIG. 3 is a cross-sectional view of the display device of FIG. 2 taken along line I-I′;

FIGS. 4A, 4B, 4C, 4D, and 4E are fingerprint images showing resolution of a fingerprint according to a thickness of a window according to an embodiment;

FIG. 5 is a block diagram illustrating a display device according to an embodiment.

FIG. 6 is a circuit diagram illustrating a pixel and a photo sensor according to an embodiment;

FIG. 7 is a plan view showing an arrangement between pixels and photo sensors according to an embodiment;

FIG. 8 illustrates graphs showing an example of a main peak wavelength of first to third lights;

FIG. 9 is a plan view showing an arrangement between light-guiding areas of a window according to an embodiment;

FIG. 10 is a plan view showing an arrangement between light-guiding areas of a window according to another embodiment;

FIG. 11 is a plan view showing an arrangement between light-guiding areas of a window according to another embodiment;

FIG. 12 is a plan view showing an arrangement between pixels and light-guiding areas according to an embodiment;

FIG. 13 is a cross-sectional view taken along line II-II′ of FIGS. 7 and 12 according to an embodiment;

FIG. 14 is a cross-sectional view showing a flow of light for fingerprint detection in FIG. 13; and

FIG. 15 is a cross-sectional view taken along line II-II′ of FIGS. 7 and 12 according to another embodiment.

### DETAILED DESCRIPTION OF THE EMBODIMENTS

Embodiments of the present disclosure address a problem in which any of a plurality of touch lines overlapping data fan-out line or scan fan-out line produce a parasitic capacitance between the touch line and the data fan-out line or between the touch line and the scan fan-out line. Due to the parasitic capacitance, a touch signal of the touch line may be affected by a data voltage of the data fan-out line or a scan control signal of the scan fan-out line, and thus, a touch sensing error may occur.

Embodiments of the present disclosure provide a display device capable of preventing a touch signal of a touch line from being affected by a data voltage of a data fan-out line or a scan control signal of a scan fan-out line.

The present disclosure now will be described more fully hereinafter with reference to the accompanying drawings, in which various embodiments are shown. This present disclosure may, however, be embodied in many different forms, and should not be construed as limited to the embodiments set forth herein. Rather, these embodiments are provided so that this disclosure will be thorough and complete, and will fully convey the scope of the present disclosure to those skilled in the art. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third” etc. may be used herein to describe various elements, components, regions, layers or sections, these elements, components, regions, layers or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As used herein, the terms “comprises,” “comprising,” “includes,” and “including” mean the presence of stated features, regions, integers, steps, operations, elements, or components, but do not preclude the presence or addition of one or more other features, regions, integers, steps, operations, elements, components, or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure present disclosure will be described in detail with reference to the accompanying drawings.

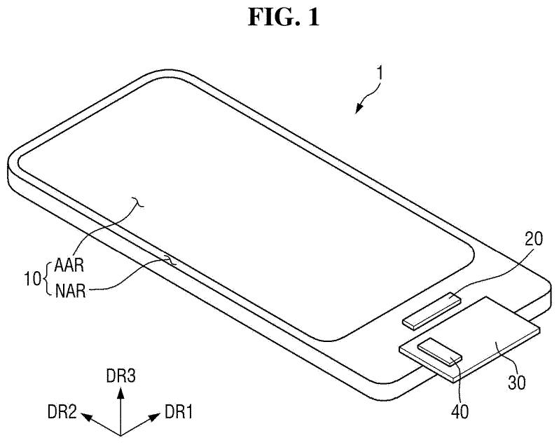

FIG. 1 is a perspective view of a display device according to an embodiment.

In FIG. 1, a first direction DR1, a second direction DR2, and a third direction DR3 are shown. The first direction DR1 is a direction parallel to a first side of a display device 1 in a plan view, for example, a horizontal direction of the display device 1. The second direction DR2 may be a direction parallel to a side of the display device 1 that meets the first side of the display device 1 in a plan view, for example, a vertical direction of the display device 1. In the following description, the first direction DR1 indicates the right direction in a plan view, a direction opposite to the first direction DR1 indicates the left direction in a plan view, the second direction DR2 indicates the upper direction in a plan view, and a direction opposite to the second direction DR2 indicates the lower direction in a plan view. The third direction DR3 may be a thickness direction of the display device 1. However, it is to be understood that the described directions are intended to mean relative directions, and the present disclosure is not limited to the directions described in the embodiments.

Unless otherwise defined, an “upper portion” and an “upper surface” shown with respect to the third direction DR3 refer to a display surface with respect to a display panel 10, and a “lower portion”, a “lower surface”, and a “rear surface” refer to an opposite side of the display surface with respect to the display panel 10.

The display device 1 may include various electronic devices that provide a display screen. Examples of the display device 1 may include, but are not limited to, a mobile phone, a smartphone, a tablet personal computer (PC), a mobile communication terminal, an electronic notebook, a personal digital assistant (PDA), a portable multimedia player (PMP), a navigation device, an ultra mobile PC (UMPC), a television, a game machine, a wrist watch-type electronic device, a head-mounted display, a personal computer monitor, a notebook computer, a vehicle instrument panel, a digital camera, a camcorder, an external billboard, an electronic billboard, various medical devices, various inspection devices, various household appliances which display an image or a video at a display area such as refrigerators and washing machines, an Internet-of-Things (IoT) device, and the like. Archetypal examples of the display device 1 may include smartphones, tablet PC, and notebook computers, but are not limited thereto.

The display device 1 may include the display panel 10, a panel driving circuit 20, a circuit board 30, and a read-out circuit 40.

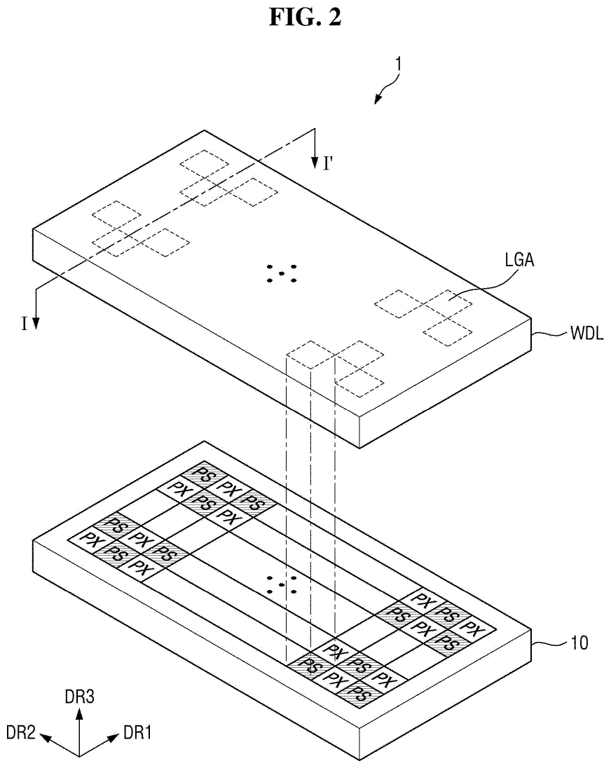

The display panel 10 includes an active area AAR and a non-active area NAR. The active area AAR includes a display area where an image is displayed. The active area AAR may completely overlap the display area. A plurality of pixels PX (FIG. 2) may be disposed in the display area to display an image.

Also, the active area AAR may further include a fingerprint detecting area. The fingerprint detecting area is an area which reacts to light and is configured to detect the amount and/or wavelength of incident light. The fingerprint detecting area may overlap the display area. For example, the fingerprint detecting area may be defined to be completely identical to the active area AAR. In this case, the entire surface of the active area AAR may be utilized as an area for fingerprint detection. A plurality of photo sensors PS (FIG. 2) configured to react to light may be disposed in the fingerprint detecting area.

The non-active area NAR is disposed around the active area AAR. The non-active area NAR may be a bezel region. The non-active area NAR may surround all sides (four sides in the drawing) of the active area AAR, but is not limited thereto.

The non-active area NAR may be disposed around the active area AAR. The panel driving circuit 20 may be disposed in the non-active area NAR. The panel driving circuit 20 may output signals and voltages for driving the plurality of pixels PX and/or the plurality of photo sensors PS. The panel driving circuit 20 may be formed as an integrated circuit (IC) and mounted on the display panel 10. Signal lines for transmitting signals between the panel driving circuit 20 and the active area AAR may be further disposed in the non-active area NAR.

Also, the read-out circuit 40 may be disposed in the non-active area NAR. The read-out circuit 40 may be connected to each of photo sensor PS through the signal line and may detect a fingerprint input from a user by receiving current flowing in each photo sensor PS. The lea-out circuit 40 may be formed as a IC and may be attached onto a display circuit board by a chip-on-film (COF) method, but the present disclosure is not limited thereto. For example, the read-out circuit 40 may be attached onto the display circuit board by a chip-on-glass (COG), chip-on-plastic (COP), or ultrasonic bonding method.

The circuit board 30 may be attached onto one end of the display panel 10 by using an anisotropic conductive film (ACF). Lead lines of the circuit board 30 may be electrically connected to display pads of the display panel 10. The circuit board 30 may be a flexible printed circuit board or a flexible film such as a chip-on-film.

FIG. 2 is a perspective view illustrating a display panel and window of a display device according to an embodiment.

Referring to FIG. 2, the display device 1 may further include a window WDL disposed on the display panel 10.

In the display panel 10, a plurality of integrated pixels PX and a plurality of photo sensors PS may be disposed. The plurality of pixels PX and the plurality of photo sensors PS may be disposed in various ways along the first direction DR1 and the second direction DR2.

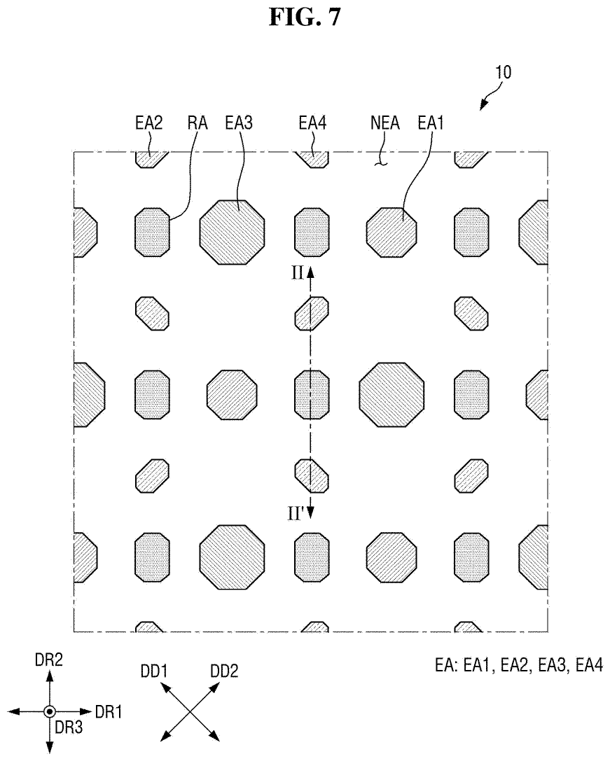

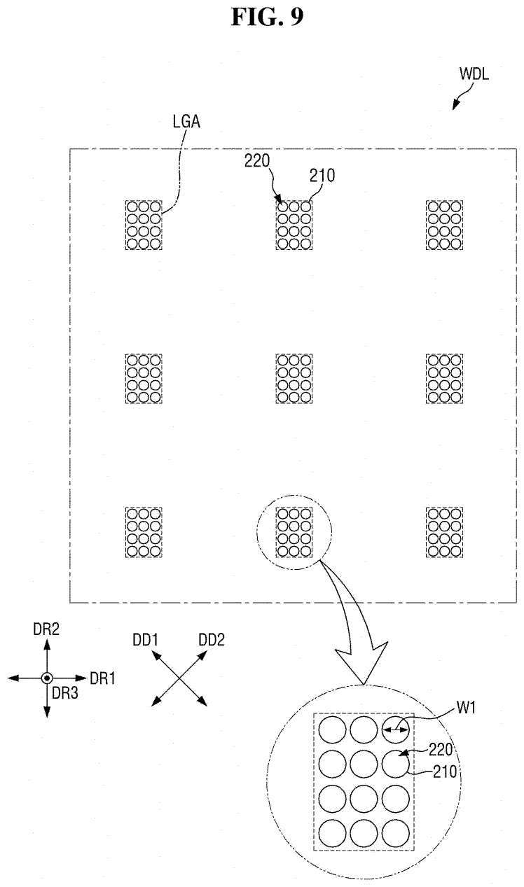

The window WDL may be disposed in an upper portion of the display panel 10 to cover an upper surface of the display panel 10. The window WDL may include a plurality of light-guiding areas LGA. Each of the plurality of light-guiding areas LGA may overlap each of the plurality of photo sensors PS of the display panel 10 in the third direction DR3, respectively. The light-guiding areas LGA may be regions that provide a passage of light through which light reflected from the window WDL is incident on the photo sensors PS. The light-guiding areas LGA may have a one-to-one correspondence with the photo sensors PS. The light-guiding areas LGA are disposed on light-sensing portions RA (FIG. 7), and may overlap the light-sensing portion RA in the third direction DR3. The arrangement relationship of the light-guiding areas LGA in a plan view will be described in detail below with reference to FIGS. 9, 10, 11, and 12.

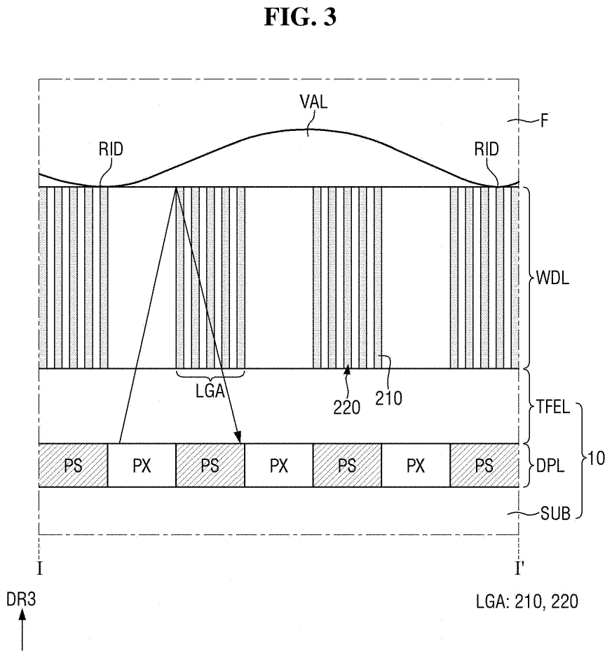

FIG. 3 is a cross-sectional view of the display device of FIG. 2 taken along line I-I′.

Referring to FIG. 3, the display panel 10 may include a substrate SUB, and a display layer DPL and an encapsulation layer TFEL which are disposed on the substrate SUB.

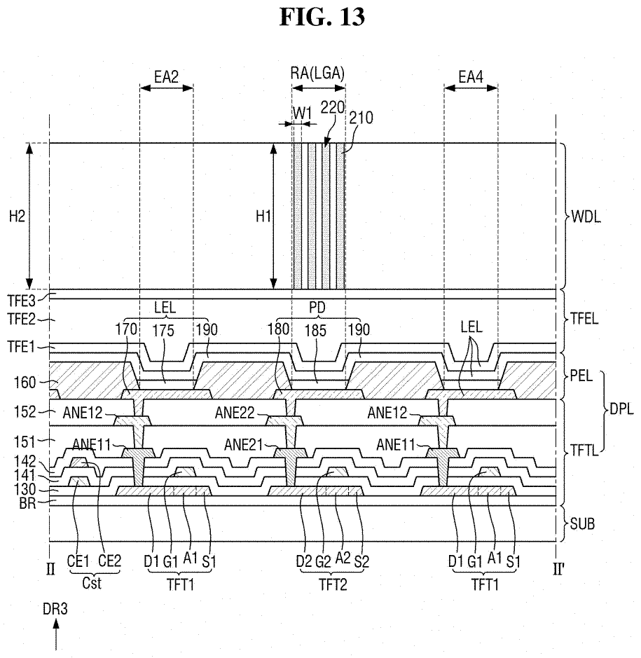

The display layer DPL includes a thin film transistor layer that applies a signal to the pixel PX and the photo sensor PS, and a photoelectric element layer having a light-emitting element LEL (FIG. 13) of the pixel PX and a photoelectric conversion element PD (FIG. 13) of the photo sensor PS. The light-emitting element of the pixel PX may emit light in a wavelength range of visible light. The light emitted from the pixel PX may function as a light source of the photo sensor PS. The photoelectric conversion element of the photo sensor PS may detect the light in the visible light wavelength range reflected from the upper surface of the window WDL and convert the detected light into an electrical signal.

The window WDL may be disposed on an upper surface of the encapsulation layer TFEL. The window WDL may protect the upper surface of the display panel 10. The window WDL may be attached to the upper surface of the display panel 10 using a transparent adhesive member. The window WDL may be made of a transparent material so that light can pass therethrough. The window WDL may transmit not only light in the visible light wavelength range, but also infrared light or ultraviolet light. The window WDL may have a refractive index of 1.4 to 1.6, but is not limited thereto.

The window WDL may be glass or plastic. When the window WDL is plastic, the window WDL may include a transparent polyimide film. The window WDL may be formed to have a thickness of at least 0.2 mm to protect the upper surface of the display panel 10, but the present disclosure is not limited thereto. For example, the window WDL may be ultra thin glass UTG in a thickness of 0.1 mm or less.

Each of a plurality of through holes 210 penetrating the window WDL and filling member 220 may be defined in each of the light-guiding areas LGA. The plurality of through holes 210 and the filling members 220 of the light-guiding areas LGA may guide the light reflected from the window WDL so that the light can be incident on the photo sensor PS.

Each of the through holes 210 may be a passage through which light reflected from a ridge RID and a valley VAL of a fingerprint F is incident to the photo sensor PS. Each of the through holes 210 may overlap the photo sensor PS in the third direction DR3. Although each of the photo sensors PS overlaps five through holes 210 in the third direction DR3 in FIG. 3, the number of through holes 210 overlapping each of the photo sensors PS in the third direction DR3 is not limited thereto.

The filling member 220 may be disposed in the through holes 210 and may completely fill the space formed by the through holes 210. The filling member 220 may be positioned in a portion of the window WDL and spaced apart by the through holes 210. The filling member 220 may include a material that transmits light in the visible light wavelength range. The filling member 220 may include a material that blocks light other than light in the visible light wavelength range, e.g., ultraviolet light or infrared light.

The filling member 220 may have a refractive index of 95% to 105% of the refractive index of the window WDL. That is, since the through holes 210 of the window WDL is filled with the filling member 220 instead of air, the through holes 210 are prevented from being visually recognized from the outside due to the difference in refractive index between the window WDL and air.

The filling member 220 may be a transparent organic layer or inorganic layer that can transmit light. For example, the filling member 220 may be an organic layer such as, for example, acryl resin, epoxy resin, phenolic resin, polyamide resin, or polyimide resin. In particular, the filling member 220 may include a silicone resin having a functional group of a thiol-ene group, but is not limited thereto.

FIG. 3 is a cross-sectional view showing a state in which a user's finger is in contact with the window WDL of the display device 1. The fingerprint F of the finger is composed of ridges RID having a unique pattern and valleys VAL disposed between the ridges RID.

Light output from the pixel PX may be reflected from the upper surface of the window WDL. The light reflected from the upper surface of the window WDL may be collected to the photo sensor PS by the through holes 210 and the filling member 220 of the light-guiding area LGA. The light output from the pixel PX may be reflected from the ridge RID and the valley VAL of the fingerprint F. At this time, the amount of light reflected from the ridge RID of the fingerprint F may be different from the amount of light reflected from the valley VAL. An electrical signal (i.e., sensing current) flowing in the photoelectric conversion element of each of the photo sensors PS may be different according to the difference in the amount of light. The read-out circuit may identify a pattern of the fingerprint F of the finger according to the difference in the electrical signal.

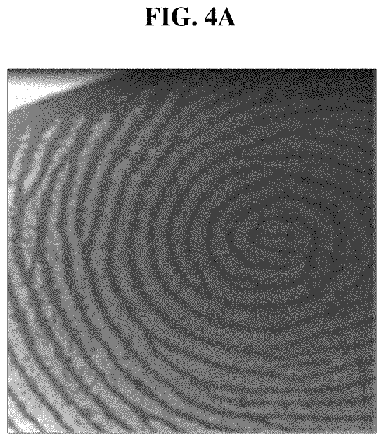

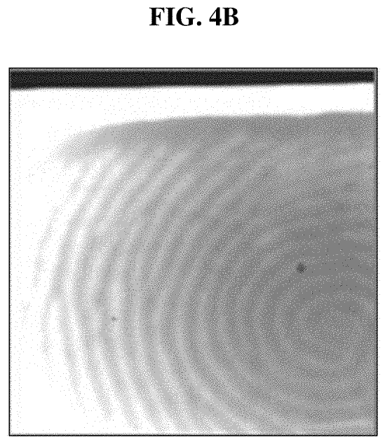

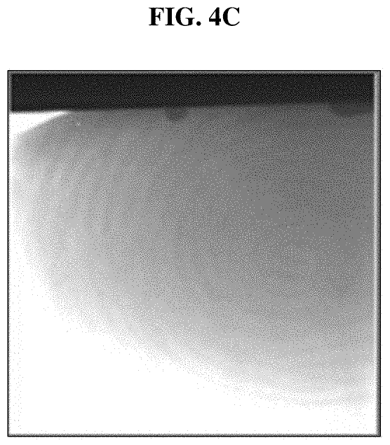

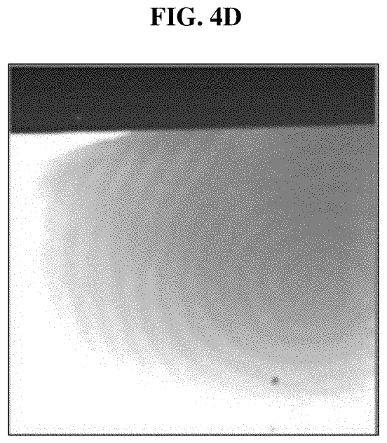

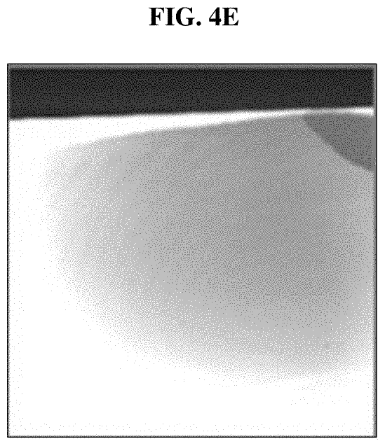

Meanwhile, when the light reflected from the upper surface of the window WDL is incident on the photo sensor PS, the degree of scattering of the light within the window WDL may be different according to the thickness of the window WDL. Hereinafter, a difference in resolution of the fingerprint F according to the thickness of the window WDL will be discussed in conjunction with FIGS. 4A, 4B, 4C, 4D, and 4E to FIG. 3.

FIGS. 4A, 4B, 4C, 4D, and 4E are fingerprint images showing resolution of a fingerprint according to a thickness of a window according to an embodiment.

FIG. 4A is a fingerprint image of a display device without a window WDL, FIG. 4B is a fingerprint image of a display device provided with a window WDL having a thickness of 0.1 mm, FIG. 4C is a fingerprint image of a display device provided with a window WDL having a thickness of 0.2 mm, FIG. 4D is a fingerprint image of a display device provided with a window WDL having a thickness of 0.3 mm, and FIG. 4E is a fingerprint image of a display device provided with a window WDL having a thickness of 0.5 mm.

Referring to FIGS. 4A, 4B, 4C, 4D, and 4E, a resolution of a fingerprint F image decreases as the thickness of the window WDL increases. The resolution of the fingerprint F image is determined according to the sharpness, luminance, or degree of blur of the fingerprint F image. It can be seen that the lower the resolution of the fingerprint F image, the lower the sharpness or luminance of the fingerprint F image, and the greater the degree of blur of the fingerprint F image. Although not limited thereto, when the thickness of the window WDL is 0.2 mm or more, the resolution of the fingerprint F image is reduced, and thus the user's fingerprint pattern may not be substantially recognized.

However, the above-listed thicknesses of the window WDL are merely exemplary values for comparing the resolutions of the fingerprint F images under the same conditions. When the structure of the display device is modified, the relationship of the thickness of the window WDL and the resolution of the fingerprint image may also be changed. In this case, even when the thickness of the window WDL is 0.2 mm or less, a suitable resolution of the fingerprint F image may be obtained.

For example, some light incident on the photo sensor PS may be scattered by ion particles present in the window WDL. The degree of scattering of light incident on the photo sensor PS may increase as the thickness of the window WDL increases. When the scattered light is incident on the photo sensor PS, it may act as noise light that does not contribute to the electrical signal of the photo sensor PS. Therefore, as the thickness of the window WDL increases, the amount of noise light may increase and the resolution of the fingerprint F image may decrease.

Referring back to FIG. 3, even when the window WDL in the display device 1 is thick enough to protect the display panel 10, the amount of noise light incident on the photo sensor PS may be reduced or minimized and the resolution degradation of the fingerprint F image may be reduced or minimized.

The window WDL includes the through holes 210 and the filling member 220 disposed in the through holes 210, thereby providing a path of the light reflected from the upper surface of the window WDL. That is, the reflected light moves along the through hole 210 and the filling member 220 so that the scattering of the light in the window WDL may be minimized.

In addition, the filling member 220 may transmit only light in the visible light wavelength range and block external light in the ultraviolet or infrared wavelength range which acts as noise light to the photo sensor PS. Therefore, the filling member 220 may increase the amount of signal light that is emitted from the light-emitting element of the pixel PX and then reflected from the fingerprint F on the upper surface of the window WDL. On the other hand, the filling member 220 may block light provided from an external source regardless of the light-emitting element, thereby minimizing the amount of noise light incident on the photo sensor PS.

Also, the filling member 220 may be made of a transparent material having a refractive index of 95% to 105% of the refractive index of the window WDL. Accordingly, it is possible to prevent the through holes 210 from being visually recognized from the outside of the display device 1.

According to the display device 1 in accordance with the present embodiment, the window WDL includes the light-guiding areas LGA that provide a path of light incident on the photo sensor PS, thereby reducing the amount of light scattered within the window WDL and increasing the amount of signal light that is emitted from the light-emitting element and then reflected from the upper surface of the window WDL. Accordingly, the display device 1 may identify a fingerprint F image with an improved resolution.

Hereinafter, the structure of the display device 1 according to the present embodiment will be described in further detail.

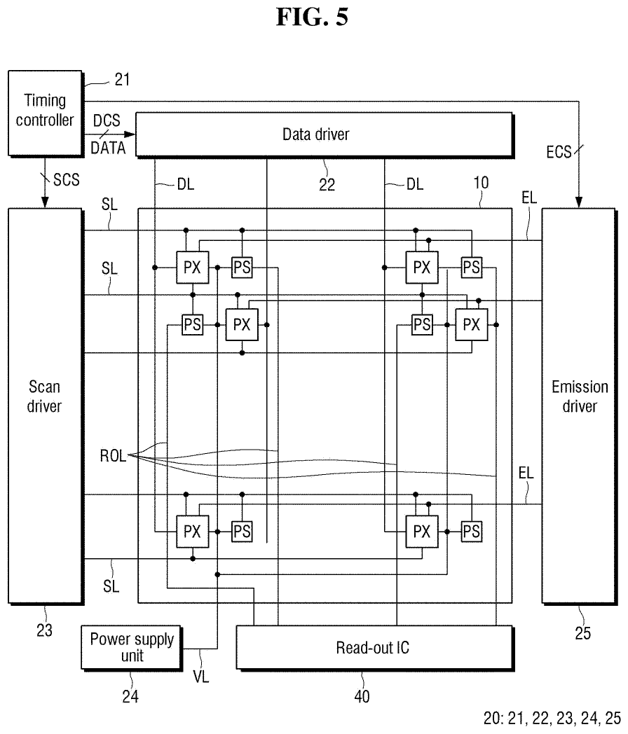

FIG. 5 is a block diagram illustrating a display device according to an embodiment.

Referring to FIG. 5, the pixels PX and the photo sensors PS of the display panel 10 may be driven by the panel driving circuit 20.

The panel driving circuit 20 includes a data driver 22 configured to drive the pixels PX of the display panel 10, a scan driver 23 configured to drive the pixels PX and the photo sensors PS, and a timing controller 21 configured to control driving timing of the data driver 22 and the scan driver 23. Also, the panel driving circuit 20 may further include a power supply unit 24 and an emission driver 25.

The timing controller 21 receives an image signal provided from the outside of the display device 1. The timing controller 21 may output image data DATA and a data control signal DCS to the data driver 22. Also, the timing controller 21 may generate a scan control signal SCS for controlling operating timing of the scan driver 23 and an emission driving signal ECS for controlling operating timing of the emission driver 25.

The data driver 22 may convert the image data DATA into analog data voltages and output the analog data voltages to the data lines DL. The scan driver 23 may generate scan signals according to the scan control signal SCS, and sequentially output the scan signals to the scan lines SL.

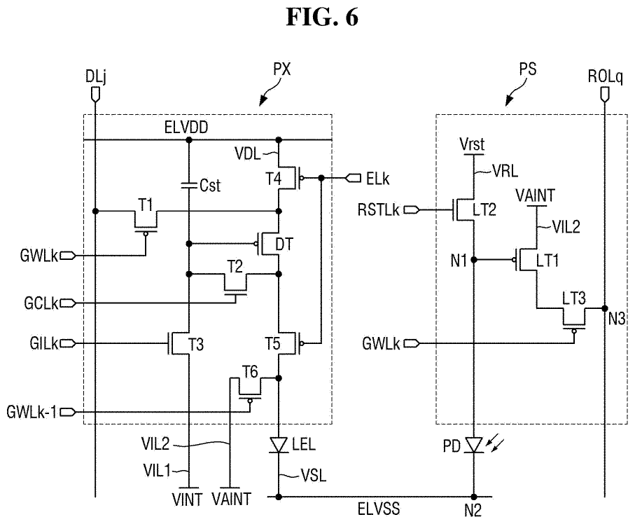

The power supply unit 24 may generate a driving voltage ELVDD (FIG. 6) and supply the driving voltage ELVDD to a power supply voltage line VL, and may generate a common voltage ELVSS (FIG. 6) and supply the common voltage ELVSS to the power supply voltage line VL. The power supply voltage line VL may include a driving voltage line and a common voltage line. The driving voltage ELVDD may be a high potential voltage for driving the light-emitting element and the photoelectric conversion element, and the common voltage may be a low potential voltage for driving the light-emitting element and the photoelectric conversion element. That is, the driving voltage may have a higher potential than that of the common voltage.

The emission driver 25 may generate emission signals according to the emission driving signal ECS and sequentially output the emission signals to the emission lines EL.

The read-out circuit 40 may be connected to each photo sensor PS through a read-out line ROL, and may receive a current flowing in each photo sensor PS to detect a fingerprint input from the user. The read-out circuit 40 may generate fingerprint detection data according to the magnitude of the current detected by each photo sensor PS and transmit the fingerprint detection data to a processor. The processor may analyze the fingerprint detection data and determine whether the user's fingerprint matches a preset fingerprint through comparison with the preset fingerprint. When the preset fingerprint is identical to the fingerprint detection data transmitted from the read-out circuit 40, the processor may perform set functions.

The display panel 10 further includes a plurality of pixels PX, a plurality of photo sensors PS, a plurality of scan lines SL connected to the plurality of pixels PX and the plurality of photo sensors PS, a plurality of data lines DL and a plurality of emission lines EL which are connected to the plurality of pixels PX, and a plurality of read-out lines ROL connected to the plurality of photo sensors PS.

Each of the pixels PX may be connected to at least one of the scan lines SL, one of the data lines DL, at least one of the emission lines EL, and the power supply voltage line VL.

Each of the photo sensors PS may be connected to one of the scan lines SL, one of the read-out lines ROL, and the power supply voltage line VL.

The plurality of scan lines SL may respectively connect the scan driver 23 to the plurality of pixels PX and the plurality of photo sensors PS. The plurality of scan lines SL may provide scan signals output from the scan driver 23 to the plurality of pixels PX and the plurality of photo sensor PS, respectively.

The plurality of data lines DL may respectively connect the data driver 22 to the plurality of pixels PX. The plurality of data lines DL may provide image data output from the data driver 22 to the plurality of pixels PX, respectively.

The plurality of emission lines EL may respectively connect the emission driver 25 to the plurality of pixels PX. The plurality of emission lines EL may provide the emission signal output from the emission driver 25 to the plurality of pixels PX, respectively.

The plurality of read-out lines ROL may respectively connect the plurality of photo sensors PS to the read-out circuit 40. The plurality of read-out lines ROL may provide a sensing current generated according to photocurrent output from each of the plurality of photo sensors PS to the read-out circuit 40. Accordingly, the read-out circuit 40 may detect the user's fingerprint.

The plurality of power supply voltage lines VL may connect the power supply unit 24 to the plurality of pixels PX and the plurality of photo sensors PS, respectively. The plurality of power supply voltage lines VL may provide the driving voltage ELVDD or the common voltage ELVSS to the plurality of pixels PX and photo sensor PS from the power supply unit 24.

FIG. 6 is a circuit diagram illustrating a pixel and a photo sensor according to an embodiment.

FIG. 6 illustrates a circuit diagram of a pixel PX connected to a k^{th} scan initialization line GILk, a k^{th} scan write line GWLk, a k^{th} scan control ine GCLk, a (k−1)^{th} scan write line GWLk-1, and a j^{th} data line DLj and a photo sensor PS connected to the k^{th} scan write line GWLk, a k^{th} reset control line RSTLk, and a q^{th} read-out line ROLq.

The pixel PX may include a light-emitting element LEL and a pixel driver configured to control the amount of light of the light-emitting element LEL. The pixel driver may include a driving transistor DT, a plurality of switch elements, and a first capacitor Cst. The switch elements may include first to sixth transistors T1, T2, T3, T4, T5, and T6. The pixel driver may be connected to a driving voltage line VDL to which the driving voltage ELVDD is applied, a common voltage line VSL to which the common voltage ELVSS is applied, a first initialization voltage line VIL1 to which a first initialization voltage VINT is applied, and a second initialization voltage line VIL2 to which a second initialization voltage VAINT is applied.

The driving transistor DT may include a gate electrode, a first electrode, and a second electrode. The driving transistor DT controls a drain-source current Isd (hereinafter referred to as a “driving current”) flowing between the first electrode and the second electrode according to a data voltage applied to the gate electrode. The driving current Isd flowing through a channel of the driving transistor DT is proportional to the square of a difference between a voltage Vgs between the first electrode and the gate electrode of the driving transistor DT and a threshold voltage as shown in Equation 1.

Isd=k′×(Vsg−Vth)² Equation 1

In Equation 1, Isd denotes a driving current which is a source-drain current flowing through the channel of the driving transistor DT, k′ denotes a proportional coefficient determined by the structure and physical characteristics of the driving transistor, Vsg denotes a voltage between the first electrode and the gate electrode, and Vth denotes a threshold voltage of the driving transistor.

The light-emitting element LEL emits light according to the driving current Isd. As the driving current Isd increases, the amount of light emitted from the light-emitting element LEL may increase.

The light-emitting element LEL may be an organic light emitting diode including an organic light-emitting layer disposed between an anode electrode and a cathode electrode. Alternatively, the light-emitting element LEL may be a quantum dot light-emitting element including a quantum dot light-emitting layer disposed between an anode electrode and a cathode electrode. Alternatively, the light-emitting element LEL may be an inorganic light-emitting element including an inorganic semiconductor disposed between an anode electrode and a cathode electrode. When the light-emitting element LEL is an inorganic light-emitting element, the light-emitting element LEL may include a micro light emitting diode or a nano light emitting diode. In FIG. 13, the anode electrode of the light-emitting element LEL corresponds to a pixel electrode 170 and a cathode electrode corresponds to a common electrode 190.

The anode electrode of the light-emitting element LEL may be connected to a second electrode of the fifth transistor T5 and a first electrode of the sixth transistor T6, and the cathode electrode may be connected to the common voltage line VSL to which the common voltage ELVSS is applied.

The first transistor T1 is turned on by the k^{th} scan write signal of the k^{th} scan write line GWLk to connect the first electrode of the driving transistor DT to the j^{th} data line DLj. Accordingly, the data voltage of the j^{th} data line DLj may be applied to the first electrode of the driving transistor DT. A gate electrode of the first transistor T1 may be connected to the k^{th} scan write line GWLk, a first electrode of the first transistor T1 may be connected to the j^{th} data line DLj, and a second electrode of the first transistor T1 may be connected to the first electrode of the driving transistor DT.

The second transistor T2 is turned on by a k^{th} scan control signal of the k^{th} scan control line GCLk to connect the gate electrode and the second electrode of the driving transistor DT. When the gate electrode and the second electrode of the driving transistor DT are connected to each other, the driving transistor DT is driven as a diode. A gate electrode of the second transistor T2 may be connected to the k^{th} scan control line GCLk, a first electrode of the second transistor T2 may be connected to the gate electrode of the driving transistor DT, and a second electrode of the second transistor T2 may be connected to the second electrode of the driving transistor DT.

The third transistor T3 is turned on by a k^{th} scan initialization signal of the k^{th} scan initialization line GILk to connect the gate electrode of the driving transistor DT to the first initialization voltage line VILI. Accordingly, a first initialization voltage VINT1 of the first initialization voltage line VIL1 may be applied to the gate electrode of the driving transistor DT. A gate electrode of the third transistor T3 may be connected to the k^{th} scan initialization line GILk, a first electrode of the third transistor T3 may be connected to the first initialization voltage line VIL1, and a second electrode of the third transistor T3 may be connected to the gate electrode of the driving transistor DT.

The fourth transistor T4 is turned on by a k^{th} emission signal of a k^{th} emission line ELk to connect the first electrode of the driving transistor DT to the driving voltage line VDL to which the driving voltage ELVDD is applied. A gate electrode of the fourth transistor T4 may be connected to the k^{th} emission line ELk, a first electrode of the fourth transistor T4 may be connected to the driving voltage line VDL, and a second electrode of the fourth transistor T4 may be connected to the first electrode of the driving transistor DT.

The fifth transistor T5 is turned on by the k^{th} emission signal of the k^{th} emission line ELk to connect the second electrode of the driving transistor DT to the anode electrode of the light-emitting element LEL. A gate electrode of the fifth transistor T5 may be connected to the k^{th} emission line ELk, a first electrode of the fifth transistor T5 may be connected to the second electrode of the driving transistor DT, and a second electrode of the fifth transistor T5 may be connected to the anode electrode of the light-emitting element LEL.

When the fourth transistor T4 and the fifth transistor T5 are all turned on, a driving current Isd of the driving transistor DT according to the voltage of the gate electrode of the driving transistor DT may flow to the light-emitting element LEL.

The sixth transistor T6 is turned on by a (k−1)^{th} scan signal of the (k−1)^{th} scan write line GWLk-1 to connect the anode electrode of the light-emitting element LEL to the second initialization voltage line VIL2. The second initialization voltage VAINT of the second initialization voltage line VIL2 may be applied to the anode electrode of the light-emitting element LEL. A gate electrode of the sixth transistor T6 may be connected to the (k−1)^{th} scan write line GWLk-1, a first electrode of the sixth transistor T6 may be connected to the anode electrode of the light-emitting element LEL, and a second electrode of the sixth transistor T6 may be connected to the second initialization voltage line VIL2.

The first capacitor Cst is formed between the gate electrode of the driving transistor DT and the driving voltage line VDL. A first capacitor electrode of the first capacitor Cst may be connected to the gate electrode of the driving transistor DT and a second capacitor electrode of the first capacitor Cst may be connected to the driving voltage line VDL.

When the first electrode of each of the driving transistor DT and the first to sixth transistors T1, T2, T3, T4, T5, and T6 is a source electrode, the second electrode thereof may be a drain electrode. Alternatively, when the first electrode of each of the driving transistor DT and the first to sixth transistors T1, T2, T3, T4, T5, and T6 is a drain electrode, the second electrode thereof may be a source electrode.

An active layer of each of the driving transistor DT and the first to sixth transistors T1, T2, T3, T4, T5, and T6 may be formed of any one of poly silicon, amorphous silicon, and an oxide semiconductor. For example, the active layer of each of the driving transistor DT and the fourth to sixth transistors T4, T5, and T6 may be made of poly silicon. The active layer of each of the second transistor T2 and the third transistor T3 may be made of an oxide semiconductor. In this case, the driving transistor DT, the first transistor T1, and the fourth to sixth transistors T4 to T6 may each be formed of a P-type MOSFET, and the second transistor T2 and the third transistor T3 may each be formed of an N-type MOSFET.

Each of the plurality of photo sensors PS may include a photoelectric conversion element PD and a sensing driver configured to control a sensing current according to photocurrent of the photoelectric conversion element PD. The sensing driver includes a plurality of sensing transistors LT1, LT2, and LT3 for controlling the sensing current generated from the photoelectric conversion element PD. The sensing driver may be connected to a reset voltage line VRL to which a reset voltage Vrst is applied, the second initialization voltage line VIL2 to which the second initialization voltage VAINT is applied, and the common voltage line VSL to which the common voltage ELVSS is applied.

Each of the photoelectric conversion elements PD may be a photodiode including a sensing anode electrode, a sensing cathode electrode, and a photoelectric conversion layer disposed between the sensing anode electrode and the sensing cathode electrode. Each of the photoelectric conversion elements PD may convert light incident from the outside into an electrical signal. The photoelectric conversion element PD may be an inorganic photodiode formed of a pn-type or pin-type inorganic material, or a photo transistor. Alternatively, the photoelectric conversion element PD may be an organic photodiode that includes an electron donating material which generates donor ions and an electron accepting material which generates acceptor ions. In FIG. 13, the sensing anode electrode of the photoelectric conversion element PD corresponds to a first electrode 180 and the sensing cathode electrode corresponds to a common electrode 190.

When exposed to external light, the photoelectric conversion element PD may generate photocharges, and the generated photocharges may be accumulated in the sensing anode electrode of the photoelectric conversion element PD. In this case, a voltage of a first node N1 electrically connected to the sensing anode electrode may increase. When the photoelectric conversion element PD is connected to the q^{th} read-out line ROLq as the first and third sensing transistors LT1 and LT3 are turned on, a sensing voltage may be accumulated in a third node N3 between the q^{th} read-out line ROLq and the third sensing transistor LT3 in proportion to the voltage of the first node N1 in which charges are accumulated.

The first sensing transistor LT1 may be turned on by the voltage of the first node N1 which is applied to a gate electrode of the first sensing transistor LT1 to connect the second initialization voltage line VIL3 to a second electrode of the third sensing transistor LT3. The gate electrode of the first sensing transistor LT1 may be connected to the first node N1, a first electrode of the first sensing transistor LT1 may be connected to the second initialization voltage line VIL2, and a second electrode of the first sensing transistor LT1 may be connected to a first electrode of the third sensing transistor LT3. The first sensing transistor LT1 may be a source follower amplifier which generates a source-drain current in proportion to the amount of charges of the first node N1 which are input to the gate electrode. Meanwhile, the first electrode of the first sensing transistor LT1 is illustrated as being connected to the second initialization voltage line VIL2, but the present disclosure is not limited thereto. For example, the first electrode of the first sensing transistor LT1 may be connected to the driving voltage line VDL or the first initialization voltage line VIL1.

The second sensing transistor LT2 may be turned on by a k^{th} reset control signal of the k^{th} reset control line RSTLk to connect the first node N1 to the reset voltage line VRL that applies a reset voltage Vrst. A gate electrode of the second sensing transistor LT2 may be connected to the k^{th} reset control line RSTLk, a first electrode of the second sensing transistor TL2 may be connected to the reset voltage line VRL, and a second electrode of the second sensing transistor LT2 may be connected to the first node N1.

The third sensing transistor LT3 may be turned on by the k^{th} scan write signal of the k^{th} scan write line GWLk to connect the second electrode of the first sensing transistor LT1 to the q^{th} read-out line ROLq. The gate electrode of the third sensing transistor LT3 may be connected to the k^{th} scan write line GWLk, the first electrode of the third sensing transistor LT3 may be connected to the second electrode of the first sensing transistor LT1, and the second electrode of the third sensing transistor LT3 may be connected to the third node N3 and the q^{th} read-out line ROLq.

An active layer of each of the first to third sensing transistors LT1, LT2, and LT3 may be formed of any one of poly silicon, amorphous silicon, and an oxide semiconductor. For example, the active layer of each of the first sensing transistor LT1 and the third sensing transistor LT3 may be made of poly silicon. The active layer of the second sensing transistor LT2 may be made of an oxide semiconductor. In this case, the first sensing transistor LT1 and the third sensing transistor LT3 may each be formed of a P-type MOSFET, and the second sensing transistor LT2 may be formed of an N-type MOSFET.

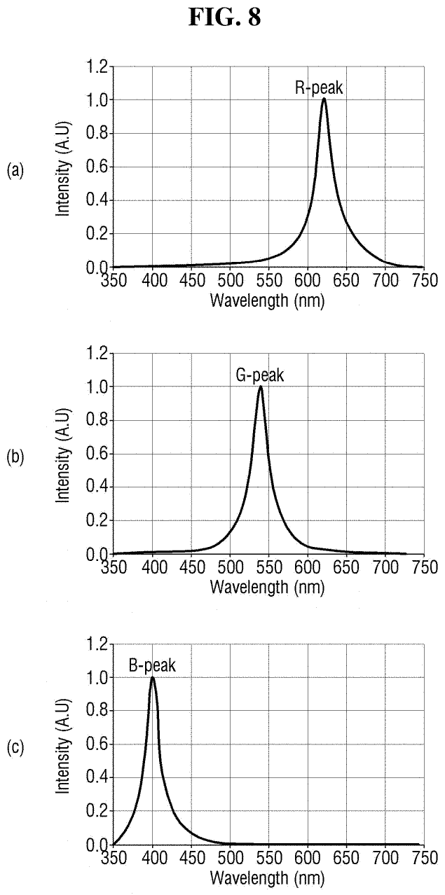

FIG. 7 is a plan view showing an arrangement between pixels and photo sensors according to an embodiment. FIG. 8 illustrates graphs showing an example of a main peak wavelength of first to third lights.

The display panel 10 may include a plurality of light-emitting portions EA (e.g., EA1, EA2, EA3, and EA4) of the plurality of pixels PX and a plurality of light-sensing portions RA of the plurality of photo sensors PS. Each of the plurality of light-emitting portions EA may be defined as an area where the pixel electrode 170 shown in FIG. 13 is exposed by an opening of a bank 160 and an area where the exposed pixel electrode 170 overlaps a light-emitting layer 175.

A first light-emitting portion EA1 may emit a first light in a red wavelength range. The first light may have a wavelength of approximately 600 nm to 750 nm (R-peak in FIG. 8(a)), but embodiments of the present disclosure are not limited thereto.

A second light-emitting portion EA2 and a fourth light-emitting portion EA4 may each emit a second light in a green wavelength range. The second light may have a wavelength of approximately 480 nm to 560 nm (G-peak in FIG. 8(b)), but embodiments of the present disclosure are not limited thereto.

A third light-emitting portion EA3 may emit a third light in a blue wavelength range. The third light may have a wavelength of approximately 370 nm to 460 nm (B-peak in FIG. 8(c)), but embodiments of the present disclosure are not limited thereto.

The first light-emitting portion EA1, the second light-emitting portion EA2, the third light-emitting portion EA3, and the fourth light-emitting portion EA4 may form one unit pixel. One unit pixel may be defined by pixels PX in the smallest unit for displaying white light.

Each of the plurality of light-sensing portions RA may be defined as an area where a first electrode 180 shown in FIG. 13 is exposed by the opening of the bank 160 and an area where the exposed first electrode 180 overlaps a photoelectric conversion layer 185.

A non-emission area is disposed between the light-emitting portions EA of the pixels PX. In addition, a non-sensing area is disposed between the light-sensing portions RA of the photo sensor PS. In the following description, an area where the non-emission area and the non-sensing area overlap each other will be referred to as a peripheral portion NEA. The bank 160 may be disposed in the peripheral portion NEA.

The plurality of light-emitting portions EA1, EA2, EA3, and EA4 may be disposed apart from each other in the first direction DR1 and the second direction DR2. For example, the first light-emitting portions EA1 and the third light-emitting portions EA3 may be alternately arranged in the first direction DR1 and the second direction DR2. The second light-emitting portions EA2 and the fourth light-emitting portions EA4 may be alternately arranged in the first direction DR1 and the second direction DR2.

A plurality of light-emitting portions EA1, EA2, EA3, and EA4 may be alternately arranged in diagonal directions DD1 and DD2 between the first direction DR1 and the second direction DR2. A first diagonal direction DD1 is a direction inclined at 45° to the first and second directions DR1 and DR2, and a second diagonal direction DD2 is a direction that intersects the first diagonal direction DD1. For example, the first light-emitting portion EA1 and the fourth light-emitting portion EA4 may be alternately arranged in the first diagonal direction DD1. The third light-emitting portions EA3 and the second light-emitting portions EA2 may be alternately arranged in the first diagonal direction DD1. The first light-emitting portions EA1 and the second light-emitting portions EA2 may be alternately arranged in the second diagonal direction DD2, and the third light-emitting portions EA3 and the fourth light-emitting portions EA4 may be arranged in the second diagonal direction DD2.

The light-sensing portion RA may be disposed between the second light-emitting portion EA2 and the fourth light-emitting portion EA4 adjacent to each other in the first direction DR1, and may be disposed between the first light-emitting portion EA1 and the third light-emitting portion EA3 adjacent to each other in the second direction DR2.

The plurality of light-emitting portions EA1, EA2, EA3, and EA4 may each have a different size from one another. The size of the first light-emitting portion EA1 may be larger than the size of each of the second light-emitting portion EA2 and the fourth light-emitting portion EA4, and may be smaller than the size of the third light-emitting portion EA3. The size of the second light-emitting portion EA2 may be substantially the same as the size of the fourth light-emitting portion EA4. The size of light-sensing portion RA is smaller than the size of each of the first light-emitting portion EA1 and the third light-emitting portion EA3, but larger than the size of each of the second light-emitting portion EA2 and the fourth light-emitting portion EA4.

The first light-emitting portion EA1, the second light-emitting portion EA2, the third light-emitting portion EA3, the fourth light-emitting portion EA4, and the light-sensing portion RA may have an octagonal planar shape, but are not limited thereto. The first light-emitting portion EA1, the second light-emitting portion EA2, the third light-emitting portion EA3, the fourth light-emitting portion EA4, and the light-sensing portion RA may have a quadrilateral planar shape, such as a rhombus, or another polygonal planar shape, but are not limited thereto.

FIG. 9 is a plan view showing an arrangement between light-guiding areas of a window according to an embodiment.

The window WDL may include a plurality of light-guiding areas LGA. The light-guiding areas LGA may be spaced apart from one another along the first direction DR1 and the second direction DR2. A plurality of through holes 210 is defined in each of the plurality of light-guiding areas LGA which may include a plurality of filling members 220 that fill each of the through holes 210. In this embodiment, twelve through holes 210 are disposed in one light-guiding area LGA, but the number of through holes 210 is not limited thereto.

In the display device 1 according to the present embodiment, each of the plurality of through holes 210 may have a circular shape in a plan view. In this case, a diameter W1 of each of the plurality of through holes 210 in one direction may be 410 nm to 580 nm. That is, the diameter W1 of the through hole 210 may be close to a wavelength of visible light. Accordingly, visible light that is reflected from the window WDL and travels through the through hole 210 may output the maximum intensity (see R-peak, G-peak, B-peak in FIG. 8).

Since the diameter W1 of the through hole 210 is closest to a wavelength range of 480 nm to 560 nm in which the second light (i.e., light in the green wavelength range) has the maximum intensity, the photo sensor PS may more easily detect the second light emitted from the second light-emitting portion EA2 or the fourth light-emitting portion EA4 among the plurality of pixels PX, although not limited thereto.

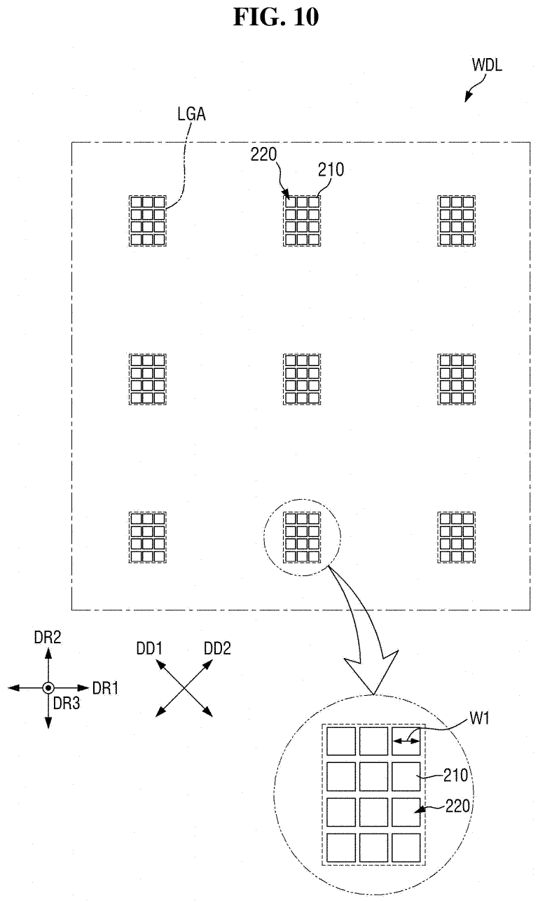

In FIG. 10, twelve through holes 210 are disposed in one light-guiding area LGA, but the number of through holes 210 is not limited thereto. For example, when diameter width W1 of the through hole 210 is 410 nm to 580 nm and the width of the light-sensing portion RA in one direction is approximately 20 MI, at least twenty through holes 210 may be disposed in one light-guiding area LGA.

FIG. 10 is a plan view showing an arrangement between light-guiding areas of a window according to another embodiment.

Referring to FIG. 10, the embodiment shown in FIG. 10 is different from the embodiment shown in FIG. 9 in that the light-guiding area LGA of the window WDL includes through holes 210 having a quadrilateral shape in a plan view. A filling member 220 is disposed in the through holes 210 and a diameter W1 of each through hole 210 in one direction may be approximately 410 nm to 580 nm. The above structure is the same as that in the embodiment shown in FIG. 9.

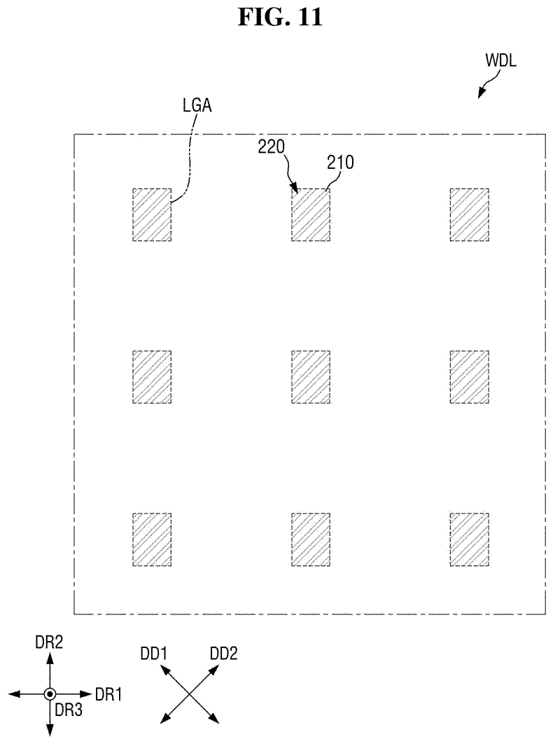

FIG. 11 is a plan view showing an arrangement between light-guiding areas of a window according to another embodiment.

Referring to FIG. 11, the embodiment shown in FIG. 11 is different from the above-described embodiments in that each of through holes 210 having a linear shape extending in one direction in a plan view is defined in a light-guiding area LGA of a window WDL. A filling member 220 may be disposed in the through holes 210, and a diameter of each through holes 210 in one direction may be approximately 410 nm to 580 nm. The above structure is the same as those in the above-described embodiments.

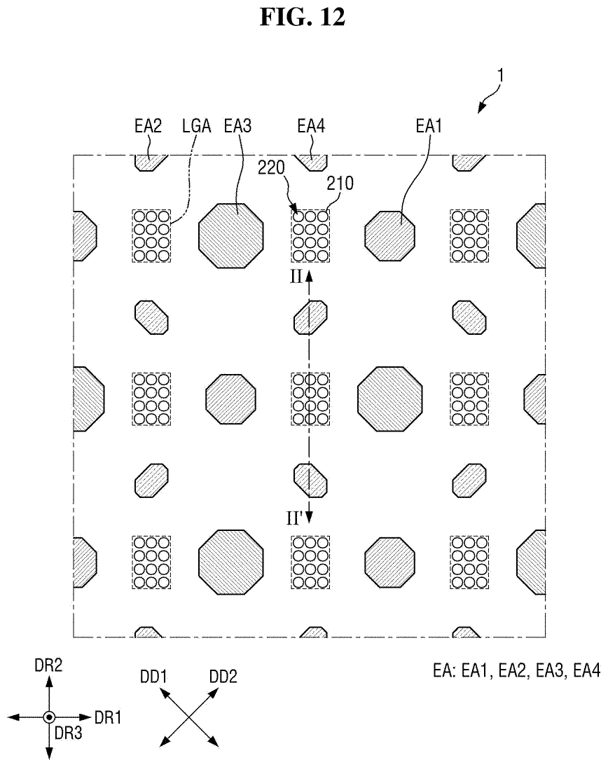

FIG. 12 is a plan view showing an arrangement between pixels and light-guiding areas according to an embodiment.

FIG. 12 is a plan view of a display device 1, showing a plurality of light-emitting portions EA disposed in a display panel 10 and a plurality of light-guiding areas LGA disposed in a window WDL simultaneously. In FIG. 12, each of the plurality of light-guiding areas LGA entirely overlaps each of the light-sensing portions RA (FIG. 7) of the display panel 10 in the third direction DR3, the arrangement between the light-guiding areas LGA is substantially the same as that of the light-sensing portions RA. The light-sensing portions RA are omitted in FIG. 12 for clarity.

Specifically, the light-sensing portion RA may be disposed between the second light-emitting portion EA2 and the fourth light-emitting portion EA4 adjacent to each other in the first direction DR1 and may be disposed between the first light-emitting portion EA1 and the third light-emitting portion EA3 adjacent to each other in the second direction DR2.

The light-guiding area LGA is illustrated as having a quadrilateral shape, but is not limited thereto. For example, the light-guiding area LGA may have the same octagonal shape as the light-sensing portion RA or may have another polygonal shape.

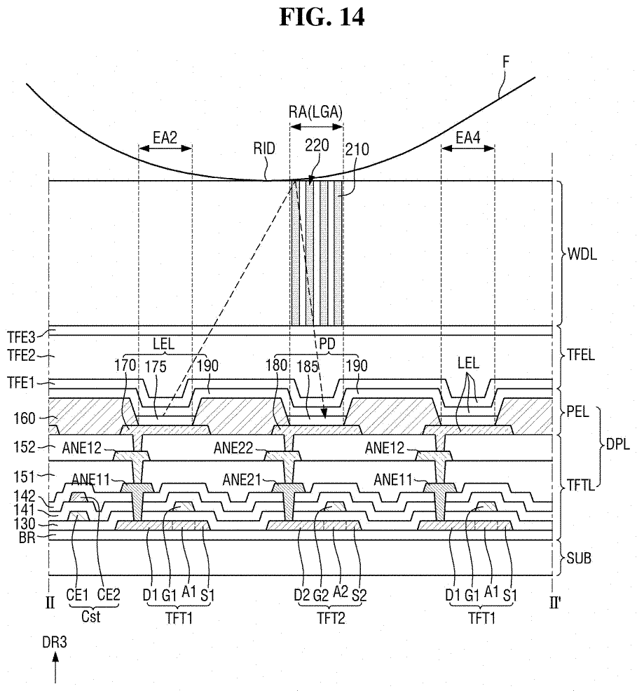

FIG. 13 is a cross-sectional view taken along line II-II′ of FIGS. 7 and 12 according to an embodiment. FIG. 14 is a cross-sectional view showing a flow of light for fingerprint detection in FIG. 13.

Referring to FIG. 13, a barrier layer BR may be disposed on the substrate SUB. The barrier layer BR may include silicon nitride, silicon oxide, or silicon oxynitride.

The thin film transistor layer TFTL disposed on the barrier layer BR may include a first thin film transistor TFT1 and a second thin film transistor TFT2. The first thin film transistor TFT1 may be the driving transistor DT or one of the first to sixth transistors T1, T2, T3, T4, T5, and T6 of FIG. 6. The second thin film transistor TFT2 may be one of the first to third sensing transistors LT1, LT2, and LT3 of FIG. 5.

First active layers of the plurality of thin film transistors TFT1 and TFT2 may be disposed on the barrier layer BR. The first active layer of the first thin-film transistor TFT1 may include polycrystalline silicon, monocrystalline silicon, low-temperature polycrystalline silicon, amorphous silicon, or an oxide semiconductor. The oxide semiconductor may include two-component compound (ABx), ternary compound (ABxCy), and four-component compound (ABxCyDz). These compounds contain, for example, indium, zinc, gallium, tin, titanium, aluminum, hafnium, zirconium, magnesium, and the like.

Each of the first active layers may include channel regions A1 and A2, source regions S1 and S2, and drain regions D1 and D2. The source regions S1 and S2 and the drain regions D1 and D2 are doped with impurities to have conductivity. Each of the channel regions A1 and A2 may be region that overlaps each of gate electrodes G1 and G2 in the third direction DR3 that is a thickness direction from the substrate SUB. The source regions S1 and S2 and the drain regions D1 and D2 may be regions that do not overlap the gate electrodes G1 and G2.

A first gate insulating layer 130 may be disposed on the first active layer. The first gate insulating layer 130 may be an inorganic layer such as, for example, a silicon nitride layer, a silicon oxynitride layer, a silicon oxide layer, a titanium oxide layer, or an aluminum oxide layer.

A first gate electrode G1 of the first thin-film transistor TFT1 and a first capacitor electrode CE1 may be disposed on the first gate insulating layer 130. Although the first gate electrode G1 and the first capacitor electrode CE1 are illustrated as being spaced apart from each other in FIG. 13, the first gate electrode G1 and the first capacitor electrode CE1 may be connected to each other. A second gate electrode G2 of the second thin film transistor TFT2 may be disposed on the first gate insulating layer 130. The first gate electrode G1, the first capacitor electrode CE1, and the second gate electrode G2 may each be a single layer or a multilayer made of any one or more of molybdenum (Mo), aluminum (Al), chromium (Cr), gold (Au), titanium (Ti), nickel (Ni), neodymium (Ne), copper (Cu), and alloys of the same.

A first interlayer insulating layer 141 may be disposed on the first gate electrode G1 of the first thin film transistor TFT1, the first capacitor electrode CE1, and the second gate electrode G2 of the second thin film transistor TFT2. The first interlayer insulating layer 141 may be an inorganic layer such as, for example, a silicon nitride layer, a silicon oxynitride layer, a silicon oxide layer, a titanium oxide layer, or an aluminum oxide layer.

A second capacitor electrode CE2 may be disposed on the first interlayer insulating layer 141. The second capacitor electrode CE2 may overlap the first capacitor electrode CE1 of the first thin film transistor TFT1 in the third direction DR3. A first capacitor Cst may be formed between the first capacitor electrode CE1 and the second capacitor electrode CE2. The second capacitor electrode CE2 may be a single layer or a multilayer made of any one or more of, for example, molybdenum (Mo), aluminum (Al), chromium (Cr), gold (Au), titanium (Ti), nickel (Ni), neodymium (Ne), copper (Cu), and alloys of the same.

A second interlayer insulating layer 142 may be disposed on the second capacitor electrode CE2. The second interlayer insulating layer 142 may include the same material as the first interlayer insulating layer 141 described above.

First anode connection electrodes ANE11 and ANE21 may be disposed on the second interlayer insulating layer 142. Each of the first anode connection electrodes ANE11 and ANE21 may be respectively connected to each of the drain regions D1 and D2 of the thin film transistors TFT1 and TFT2 through contact holes penetrating the first gate insulating layer 130, the first interlayer insulating layer 141, and the second interlayer insulating layer 142. The first anode connection electrodes ANE11 and ANE21 may each be a single layer or a multilayer made of any one or more of, for example, molybdenum (Mo), aluminum (Al), chromium (Cr), gold (Au), titanium (Ti), nickel (Ni), neodymium (Nd), copper (Cu), and alloys of the same.

A first planarization layer 151 for planarizing a step height caused by the thin film transistors TFT1 and TFT2 may be disposed on the first anode connection electrodes ANE11 and ANE21. The first planarization layer 151 may be an organic layer such as acryl resin, epoxy resin, phenolic resin, polyamide resin, or polyimide resin.

Second anode connection electrodes ANE12 and ANE22 may be disposed on the first planarization layer 151. Each of the second anode connection electrodes ANE12 and ANE22 may be respectively connected to each of the first anode connection electrodes ANE11 and ANE21 through contact holes penetrating the first planarization layer 151. The second anode connection electrodes ANE12 and ANE22 may include the same material as the first anode connection electrodes ANE11 and ANE21 described above.

A second planarization layer 152 may be disposed on the second anode connection electrodes ANE12 and ANE22. The second planarization layer 152 may include the same material as the first planarization layer 151 described above.

A photoelectric element layer PEL may be disposed on the second planarization layer 152. The photoelectric element layer PEL may include light-emitting elements LEL, photoelectric conversion elements PD, and a bank 160. The light-emitting element LEL may include the pixel electrode 170, the light-emitting layer 175, and the common electrode 190. The photoelectric conversion element PD may include the first electrode 180, the photoelectric conversion layer 185, and the common electrode 190. The light-emitting elements LEL and the photoelectric conversion elements PD may share the common electrode 190.

The pixel electrode 170 of the light-emitting element LEL may be disposed on the second planarization layer 152. The pixel electrode 170 may be provided for each pixel PX. The pixel electrode 170 may be connected to one of the second anode connection electrodes ANE12 through a contact hole penetrating the second planarization layer 152.

The pixel electrode 170 of the light-emitting element LEL may have, but is not limited to, a single layer structure of molybdenum (Mo), titanium (Ti), copper (Cu), or aluminum (Al), a laminated structure, for example, indium-tin-oxide (ITO), indium-zinc-oxide (IZO), zinc oxide (ZnO), indium oxide (In2O3), or a multi-layer structure of ITO/Mg, ITO/MgF, ITO/Ag, or ITO/Ag/ITO containing silver (Ag), magnesium (Mg), Aluminum (Al), platinum (Pt), lead (Pb), gold (Au), and nickel (Ni).

In addition, the first electrode 180 of the photoelectric conversion element PD may be disposed on the second planarization layer 152. The first electrode 180 may be provided for each photo sensor PS. The first electrode 180 may be connected to one of the second anode connection electrodes ANE22 through a contact hole penetrating the second planarization layer 152.

The first electrode 180 of the photoelectric conversion element PD may have, but is not limited to, a single layer structure of molybdenum (Mo), titanium (Ti), copper (Cu), or aluminum (Al), or a multi-layer structure of ITO/Mg, ITO/MgF, ITO/Ag, or ITO/Ag/ITO.

The bank 160 may be disposed on the pixel electrode 170 and the first electrode 180. An opening that overlaps the pixel electrode 170, thereby exposing the pixel electrode 170 may be formed in the bank 160. An area where the exposed pixel electrode 170 overlaps the light-emitting layer 175 may be defined as an emission area of each pixel PX.

Also, another opening that overlaps the first electrode 180, thereby exposing the first electrode 180 may be formed in the bank 160. The opening that exposes the first electrode 180 may provide a space in which the photoelectric conversion layer 185 of each photo sensor PS is formed, and an area where the exposed first electrode 180 overlaps the photoelectric conversion layer 185 may be defined as a photo sensing area.

The bank 160 may include an organic insulating material, such as polyacrylates resin, epoxy resin, phenolic resin, polyamides resin, polyimides rein, unsaturated polyesters resin, polyphenylenethers resin, polyphenylenesulfides resin, benzocyclobutene (BCB), or the like. In another example, the bank 160 may include an inorganic material, such as silicon nitride.

The light-emitting layer 175 may be disposed on the pixel electrode 170 of the light-emitting element LEL exposed by the opening of the bank 160. The light-emitting layer 175 may include a high molecular material or a low molecular material, and may emit visible light of red, green, or blue color for each pixel PX. The light emitted from the light-emitting layer 175 may contribute to image display.

When the light-emitting layer 175 is formed of an organic material, a hole injection layer HIL and a hole transporting layer HTL may be disposed at a lower portion of each light-emitting layer 175, and an electron injecting layer EIL and an electron transporting layer ETL may be stacked on an upper portion of the light-emitting layer 175. These layers may each be a single layer or multiple layers formed of an organic material.

The photoelectric conversion layer 185 may be disposed on the first electrode 180 of the photoelectric conversion element PD exposed by the opening of the bank 160. The photoelectric conversion layer 185 may generate photoelectric charges in proportion to light incident thereupon. The charges generated and accumulated in the photoelectric conversion layer 185 may be converted into electrical signals required for sensing.

The photoelectric conversion layer 185 may include an electron donating material and an electron accepting material. The electron donating material may generate donor ions in response to light, and the electron accepting material may generate acceptor ions in response to light. When the photoelectric conversion layer 185 is formed of an organic material, the electron donating material may include a compound subphthalocyanine (SubPc), dibutylphosphate (DBP), or the like, but is not limited thereto. The electron accepting material may include a compound such as fullerene, a fullerene derivative, and perylene diimide, but is not limited thereto.

When the photoelectric conversion layer 185 is formed of an inorganic material, the photoelectric conversion element PD may be a pn-type or pin-type photo transistor. For example, the photoelectric conversion layer 185 may have a structure in which an N-type semiconductor layer, an I-type semiconductor layer, and a P-type semiconductor layer are sequentially stacked atop one another.

When the photoelectric conversion layer 185 is formed of an organic material, a hole injection layer HIL (not shown) and a hole transporting layer HTL (not shown) may be disposed at a lower portion of each photoelectric conversion layer 185, and an electron injecting layer EIL (not shown) and an electron transporting layer ETL (not shown) may be stacked on an upper portion of the photoelectric conversion layer 185. These layers may each be a single layer or multiple layers formed of an organic material.

The light-sensing portion RA may be, but not limited to, a region which is provided with light of the same wavelength as that of light which is generated, as a light source, by adjacent light-emitting portions (e.g., EA2 and EA4).

The common electrode 190 may be disposed on the light-emitting layer 175, the photoelectric conversion layer 185, and the bank 160. The common electrode 190 may be disposed over the plurality of pixels PX and the plurality of photo sensors PS in a form that covers the light-emitting layer 175, the photoelectric conversion layer 185, and the bank 160. The common electrode 190 may include a conductive material having low work function, for example, Li, Ca, LiF/Ca, LiF/Al, Al, Mg, Ag, Pt, Pd, Ni, Au Nd, Jr, Cr, BaF, Ba or a compound or mixture thereof (e.g., a mixture of Ag and Mg, etc.). Alternatively, the common electrode 190 may include a transparent metal oxide, for example, indium-tin-oxide (ITO), indium-zinc-oxide (IZO), zinc oxide (ZnO), and the like.

The encapsulation layer TFEL may be disposed on an upper portion of the photoelectric element layer PEL. The encapsulation layer TFEL may include at least one inorganic layer and one organic layer to prevent oxygen or moisture from permeating into the light-emitting layer 175 and the photoelectric conversion layer 185 or to protect the light-emitting layer 175 and the photoelectric conversion layer 185 from foreign matter such as dust. For example, the encapsulation layer TFEL may be formed in a structure in which a first inorganic layer TFE1, an organic layer TFE2, and a second inorganic layer TFE3 are sequentially stacked atop one another in the third direction DR3. The first inorganic layer TFE1 and the second inorganic layer TFE2 may each be formed as a multi-layer in which one or more inorganic layers are alternately stacked, wherein the inorganic layers may include a silicon nitride layer, a silicon oxynitride layer, a silicon oxide layer, a titanium oxide layer, and an aluminum oxide layer. The organic layer TFE2 may be an organic layer such as acrylic resin, epoxy resin, phenolic resin, polyamide resin, polyimide resin, or the like.

The window WDL may be disposed in an upper portion of the encapsulation layer TFEL. The window WDL may include the light-guiding area LGA that overlaps the light-sensing portion RA of the photoelectric conversion element PD in the third direction DR3, as described with reference to FIG. 3. The light-guiding area LGA may include a plurality of through holes 210 and a filling member 220 that fills the through holes 210. The width W1 of each through hole 210 in one direction may be approximately 410 nm to 580 nm as described above. Since the through holes 210 and the filling member 220 extend in parallel to the third direction DR3 that is a thickness direction of the window WDL, the height of the through holes 210 and the filling member 220 in the third direction DR3 may be substantially the same as the thickness TH1 of the window WDL.

Referring to FIG. 14, light which is emitted from the light-emitting element LEL and then reflected from a fingerprint F on the upper surface of the window WDL may be incident on the photo sensor PS. The reflected light may move through the through hole 210 and the filling member 220 so that the scattering of the light in the window WDL may be minimized. In addition, the filling member 220 may block light provided from an external source regardless of the light-emitting element LEL, thereby minimizing the amount of noise light incident on the photo sensor PS. Accordingly, the display device 1 may identify a fingerprint F image with an improved resolution.

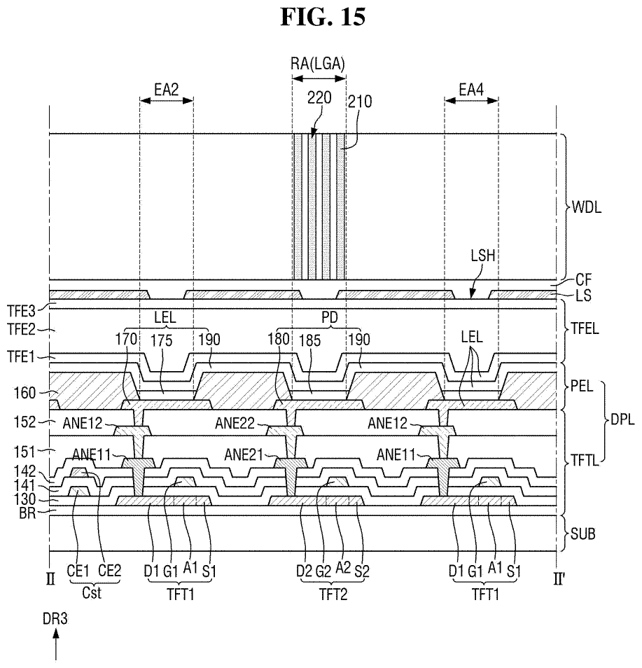

Hereinafter, a display device 1 according to another embodiment will be described. FIG. 15 is a cross-sectional view taken along line II-II′ of FIGS. 7 and 12 according to another embodiment.

In FIG. 15, a display device 1 may further include a light blocking layer LS including a plurality of light-transmitting holes LSH and a color filter CF configured to cover the light blocking layer LS.

The light blocking layer LS may be formed of photosensitive resin that can block light. For example, the light blocking layer LS may include an inorganic block pigment, such as carbon black, or an organic black pigment.

The plurality of light-transmitting holes LSH may be light-blocking openings which are defined in the light blocking layer LS. The plurality of light-transmitting holes LSH may transmit light emitted from the light-emitting element LEL or light incident on the photoelectric conversion element PD. A width of the plurality of light-transmitting holes LSH in one direction may be narrower than the widths of the light-sensing portion RA and the light-emitting portions (e.g., EA2 and EA4) in one direction. Also, the width of the plurality of light-transmitting holes LSH may be narrower than the width in one direction of the light-guiding area LGA. Accordingly, the area of the light incident on the light-sensing portion RA may be reduced. When the area of the light incident on one light-sensing portion RA is reduced, a resolution of a fingerprint that the photo sensor PS recognizes may increase.

The color filter CF may be disposed in an upper portion of the light blocking layer LS and overlap each light-emitting element LEL and each photoelectric conversion element PD. The color filter CF may transmit predetermined light emitted from the light-emitting elements LEL.

The current disclosure should not be construed as being limited to the embodiments set forth herein. Rather, these embodiments are provided so that this disclosure will be thorough and complete and will fully convey the concept of the present disclosure to those skilled in the art.

While the current disclosure have been particularly shown and described with reference to some embodiments thereof, it will be understood by one of ordinary skill in the art that various changes in form and detail may be made therein without departing from the spirit and scope of the current disclosure as defined by the following claims.

What is claimed:

1. A display device comprising:
a substrate;
a light-emitting element disposed on the substrate;
a photoelectric conversion element configured to detect light from the plurality of light-emitting portions; and
a window disposed on the light-emitting element and the photoelectric conversion element and configured to transmit light,
wherein a plurality of through holes that overlap the photoelectric conversion element in a thickness direction of the substrate are defined in the window, and
each of a plurality of filling members is disposed in each of the plurality of through holes.

2. The display device of claim 1, wherein each of the filling members is configured to transmit light in a visible light wavelength range.

3. The display device of claim 2, wherein each of the filling members is configured to block light in a wavelength range other than the visible light wavelength range.

4. The display device of claim 1, wherein a thickness of the window is 0.2 millimeter (mm) or more.

5. The display device of claim 1, wherein a thickness of the window is less than 0.2 mm.

6. The display device of claim 1, wherein each of the filling members includes one of silicon resin, urethane resin, acryl resin, epoxy resin, phenolic resin, polyamide resin, and polyimide resin.

7. The display device of claim 1, wherein each of the filling members has a functional group of a thiol-ene group.

8. The display device of claim 1, wherein a refractive index of the filling member is 95% to 105% of a refractive index of the window.

9. The display device of claim 1, wherein the light emitted from the light-emitting element has a wavelength range of visible light, and
a diameter in one direction of each of the plurality of through holes is equal to the wavelength range of the visible light.

10. The display device of claim 9, wherein the diameter in one direction of each of the plurality of through holes is 410 nanometer (nm) to 580 nm.

11. The display device of claim 1, wherein each of the plurality of through holes extends in parallel to the thickness direction of the substrate.

12. The display device of claim 11, wherein a height of each of the plurality of through holes in the thickness direction of the substrate is equal to a height of the window.

13. The display device of claim 1, wherein each of the plurality of through holes has a circular shape in a plan view.

14. The display device of claim 1, wherein each of the plurality of through holes has a linear shape extending in one direction in a plan view.

15. The display device of claim 1, wherein the light-emitting element includes a pixel electrode, an light-emitting layer, and a common electrode which are sequentially stacked in the thickness direction of the substrate, and the photoelectric conversion element includes a first electrode, a photoelectric conversion layer, and the common electrode which are sequentially stacked in the thickness direction of the substrate.

16. A display device comprising:
a substrate;
a plurality of light-emitting portions disposed on the substrate;
a plurality of light-sensing portions disposed on the substrate and configured to detect light from the plurality of light-emitting portions;
a bank configured to partition the plurality of light-emitting portions and the plurality of light-sensing portions; and
a window disposed on the bank,
wherein the window includes a plurality of light-guiding areas that overlap the plurality of light-sensing portions in a thickness direction of the substrate,
each of a plurality of through holes is defined in each of the plurality of light-guiding areas,
a plurality of filling members are disposed in the plurality of through holes, and the window and the filling member are transparent.

17. The display device of claim 16, wherein a refractive index of the filling member is 95% to 105% of a refractive index of the window.

18. The display device of claim 16, wherein each of the plurality of light guiding areas is disposed between a plurality of light-emitting portions adjacent to each other in a first direction and is disposed between a plurality of light-emitting portions adjacent to each other in a second direction that intersects the first direction.

19. The display device of claim 16, wherein a number of through holes disposed in one of the plurality of light-guiding areas is at least 12 or more.

20. The display device of claim 16, wherein the plurality of through holes do not overlap the bank in the thickness direction of the substrate.

21. The display device of claim 16, further comprising a light blocking layer disposed between the bank and the window and configured to block light,
wherein a light-transmitting hole that transmits light is defined in the light blocking layer, and a diameter in one direction of the light-transmitting hole is narrower than a diameter in one direction of the light-sensing portion.

22. The display device of claim 16, wherein the light-emitting portion is defined by a pixel electrode disposed on the substrate, the bank configured to expose the pixel electrode, and a common electrode disposed on the pixel electrode, and
the light-sensing portion is defined by a first electrode disposed on the substrate, the bank configured to expose the first electrode, and the common electrode disposed on the first electrode.
